(19) United States
(12) Patent Application Publication
(10) Pub. No.: US 2025/0309988 A1
(43) Pub. Date: Oct. 2, 2025

(54) POWER SUPPLY CIRCUIT, REPEATER, AND POWER FEEDING METHOD IN REPEATER

(71) Applicant: NEC Corporation, Tokyo (JP)

(72) Inventor: Motoyoshi KAWAI, Tokyo (JP)

(73) Assignee: NEC Corporation, Tokyo (JP)

(21) Appl. No.: 19/073,236

(22) Filed: Mar. 7, 2025

(30) Foreign Application Priority Data
Mar. 27, 2024 (JP) 2024-050636

(51) Int. Cl. H04B 10/294; G02B 6/44; H01S 5/40; H04B 10/2581; H04B 10/80

(52) U.S. Cl. CPC H04B 10/294; G02B 6/4427; H01S 5/4018; H04B 10/2581; H04B 10/808

(57) ABSTRACT

A power supply circuit includes: a direct current (DC)/DC converter connected in series to a cable including an optical fiber and a power supply line, and configured to amplify a current supplied via the power supply line; and one or more Zener diodes connected in series with respect to an output current of the DC/DC converter, and each connected in parallel with respect to an optical amplifier amplifying a signal transmitted through the optical fiber.

### INCORPORATION BY REFERENCE

This application is based upon and claims the benefit of priority from Japanese patent application No. 2024-050636, filed on Mar. 27, 2024, the disclosure of which is incorporated herein in its entirety by reference.

### TECHNICAL FIELD

The present disclosure relates to a power supply circuit, a repeater, a communication system, and a power feeding method in the repeater.

### BACKGROUND ART

A dense wavelength division multiplexing (DWDM) system is widely applied to a communication network laid on the seabed. In such a communication network, a plurality of submarine optical repeaters are inserted into a transmission path. Generally, the submarine optical repeater includes an optical amplifier using an erbium doped fiber. The optical amplifier amplifies an attenuated optical signal to an appropriate level.

In the above-described communication network, a cable laid on the seabed includes an optical fiber cable and a power supply line. The power supply line is also referred to as a system cable. The system cable is connected to a power feeding apparatus, such as a constant current source. The optical amplifier of an optical repeater is supplied with a constant current from the constant current source via the system cable. The optical amplifier includes one or more excitation laser modules connected in series with respect to the system cable. Each of the one or more excitation laser modules is supplied with a constant current via the system cable. The constant current supplied via the system cable is also referred to as a system current.

As a related art, Patent Literature 1 (International Patent Publication No. WO2022/158311) discloses a power supply circuit and an optical submarine cable. The power supply circuit described in Patent Literature 1 includes a plurality of circuit elements connected in series to each other. Each of the plurality of circuit elements is supplied with a system current from an external power source. Each of the circuit elements includes one or more Zener diodes and a current control circuit. In the power supply circuit, one or more Zener diodes are connected in series to each other.

The current control circuit includes a direct current (DC)/DC converter and a feedback circuit. The DC/DC converter inputs a predetermined voltage, and outputs a voltage adjusted based on a control signal for feedback control to a load such as a laser diode. One or more Zener diodes are connected in parallel to the DC/DC converter at a terminal inputting the predetermined voltage. The feedback circuit compares a reference voltage generated according to an output voltage of the DC/DC converter with a current detection voltage generated according to a current flowing through the load. The feedback circuit outputs a control signal representing a comparison result to the DC/DC converter.

### SUMMARY

At present, in order to increase transmission capacity in a submarine communication network, an increase in an output of a submarine optical repeater and an increase in the number of fiber pairs are required. For this reason, increasing an output of an excitation laser module is required in each of the submarine optical repeaters. However, in the submarine optical repeater having a general configuration, there is a problem that a current equal to or higher than a current supplied from a system cable cannot be supplied to the excitation laser module, and thereby a current required for a high output of the excitation laser module cannot be acquired.

In order to solve the above-described problem, it is conceivable to increase a power feeding current of power feeding equipment (PFE) installed on land, or to increase the number of excitation laser modules used in an optical amplifier (e.g., from two to four). However, an upper limit current of commonly used power feeding equipment is 1.3 A, and it is insufficient for a current (−1.8 A) allowed by a high output excitation laser module. In addition, in a case where the number of excitation laser modules is increased, a method of controlling the excitation laser module in the optical amplifier becomes complicated. Further, the number of couplers multiplexing excitation light increases, and thereby a method of distributing the excitation light to an erbium doped fiber becomes complicated. As a result, there is a problem that the number of components in the excitation module increases and the submarine optical repeater becomes large.

In the power supply circuit described in Patent Literature 1, a Zener diode supplies a predetermined voltage to a DC/DC converter, and the DC/DC converter outputs, to a load, a voltage adjusted in such a way that a reference voltage and a current detection voltage are equal to each other. By doing so, the power supply circuit described in Patent Literature 1 can supply a predetermined current to a load with high power supply efficiency in a case where a constant current is supplied to one power supply line.

However, in the power supply circuit described in Patent Literature 1, a Zener diode is connected to an input side of the DC/DC converter. In other words, the DC/DC converter is connected to a subsequent stage of the Zener diode. In Patent Literature 1, in a case where a plurality of optical amplifiers are implemented in a repeater, a set of a Zener diode and a DC/DC converter is required for each optical amplifier being a load. In addition, conversion efficiency of one DC/DC converter is approximately 80% to 90%. In the power supply circuit described in Patent Literature 1, since a plurality of DC/DC converters are connected in multiple stages, there is also a problem that the conversion efficiency decreases as the number of stages increases.

One of example objects of the present disclosure is to provide a power supply circuit, a repeater, a communication system, and a power feeding method in the repeater that are capable of increasing an output of an optical amplifier in the repeater.

In a first example aspect, a power supply circuit includes: a DC/DC converter connected in series to a cable including an optical fiber and a power supply line, and configured to amplify a current supplied via the power supply line; and one or more Zener diodes connected in series with respect to an output current of the DC/DC converter, and each connected in parallel with respect to an optical amplifier amplifying a signal transmitted through the optical fiber.

In a second example aspect, a repeater includes: one or more optical amplifiers connected in series to a cable including an optical fiber and a power supply line, and each configured to amplify a signal transmitted through the optical fiber; and a power supply circuit configured to supply current to the one or more optical amplifiers. The power supply circuit includes a DC/DC converter configured to amplify a current supplied via the power supply line, and one or more Zener diodes connected in series with respect to an output current of the DC/DC converter and each connected in parallel with respect to the optical amplifier.

In a third example aspect, a communication system includes: first and second terminal station apparatuses disposed on one end side and the other end side of a cable including an optical fiber and a power supply line; and one or more repeaters inserted in series into the cable. Each of the one or more repeaters includes one or more optical amplifiers connected in series to the cable and each configured to amplify a signal transmitted through the optical fiber, and a power supply circuit supplying current to the one or more optical amplifiers. The power supply circuit includes a DC/DC converter amplifying a current supplied via the power supply line, and one or more Zener diodes connected in series with respect to an output current of the DC/DC converter and each connected in parallel with respect to an optical amplifier.

In a fourth example aspect, a power feeding method in a repeater includes: in a repeater inserted in series into a cable including an optical fiber and a power supply line, inputting a first current supplied via the power supply line to a DC/DC converter; converting the first current into a second current larger than the first current by using the DC/DC converter; and supplying the second current from each of one or more Zener diodes connected in series with respect to an output terminal of the DC/DC converter to an optical amplifier amplifying a signal transmitted through the optical fiber.

An example advantage according to the present disclosure is that a power supply circuit, a repeater, a communication system, and a power feeding method in the repeater according to the present disclosure are capable of increasing an output of an optical amplifier in the repeater without complicating a configuration.

### BRIEF DESCRIPTION OF DRAWINGS

The above and other aspects, features and advantages of the present disclosure will become more apparent from the following description of certain example embodiments when taken in conjunction with the accompanying drawings, in which:

FIG. 1 is a block diagram illustrating a schematic configuration of a communication system according to the present disclosure;

FIG. 2 is a block diagram illustrating a schematic configuration of a repeater;

FIG. 3 is a block diagram illustrating one example of the communication system according to the present disclosure;

FIG. 4 is a block diagram illustrating a configuration example of the repeater;

FIG. 5 is a block diagram illustrating a configuration example of an optical amplifier; and

FIG. 6 is a block diagram illustrating a configuration example of a power supply circuit.

### EXAMPLE EMBODIMENT

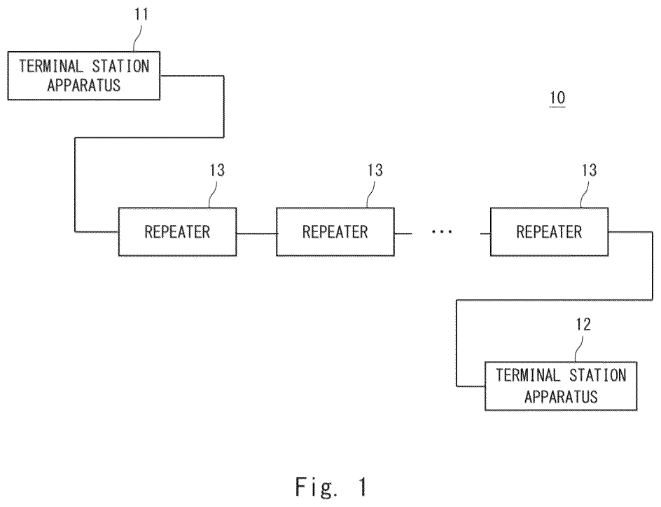

Prior to the description of an example embodiment of the present disclosure, an outline of the present disclosure will be described. FIG. 1 illustrates an example of a schematic configuration of a communication system according to the present disclosure. The communication system includes a first terminal station apparatus 11, a second terminal station apparatus 12, and one or more repeaters 13. The first terminal station apparatus 11 is disposed on one end side of a cable (communication cable), and the second terminal station apparatus 12 is disposed on the other end side of the cable. The cable includes an optical fiber and a power supply line. The one or more repeaters 13 are inserted in series into the cable.

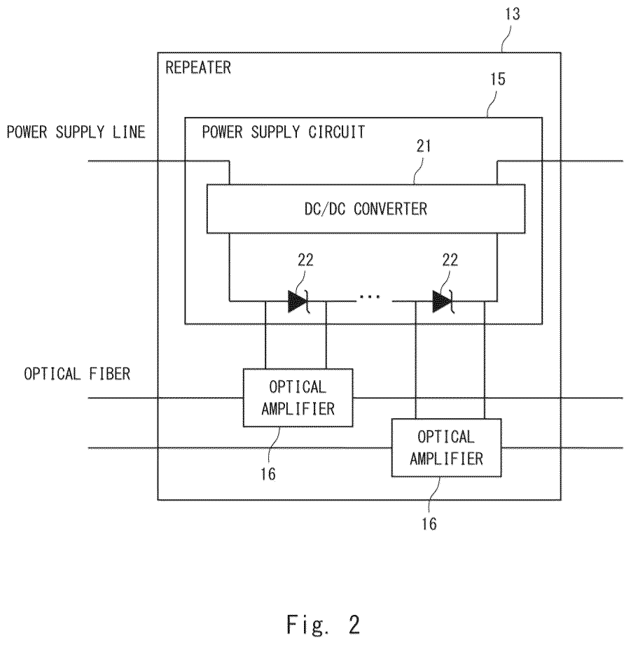

FIG. 2 illustrates a schematic configuration of the repeater 13. The repeater 13 includes a power supply circuit 15, and one or more optical amplifiers 16. Each of the one or more optical amplifiers 16 amplifies a signal transmitted through an optical fiber. The power supply circuit 15 supplies current to one or more optical amplifiers 16.

The power supply circuit 15 includes a DC/DC converter 21, and one or more Zener diodes 22. The DC/DC converter 21 amplifies a system current supplied via a power supply line included in a cable. The one or more Zener diodes 22 are connected in series with respect to an output current of the DC/DC converter 21. Each Zener diode 22 is connected in parallel with respect to the optical amplifier 16.

In the present disclosure, the power supply circuit 15 of the repeater 13 includes the DC/DC converter 21 in a preceding stage of the Zener diode 22. The DC/DC converter 21 outputs a current larger than a current supplied from the power supply line. In this case, a current increased by the DC/DC converter 21 is supplied to the optical amplifier 16. By doing so, an output of the optical amplifier 16 can be increased, as compared with a case where the current supplied from the power supply line is directly supplied to the optical amplifier 16.

Hereinafter, the example embodiment of the present disclosure will be described in detail with reference to the drawings. Note that, the following description and the drawings are omitted and simplified as appropriate for clarity of description. In addition, in the following drawings, the same elements and similar element are denoted by the same reference signs, and redundant descriptions are omitted as necessary.

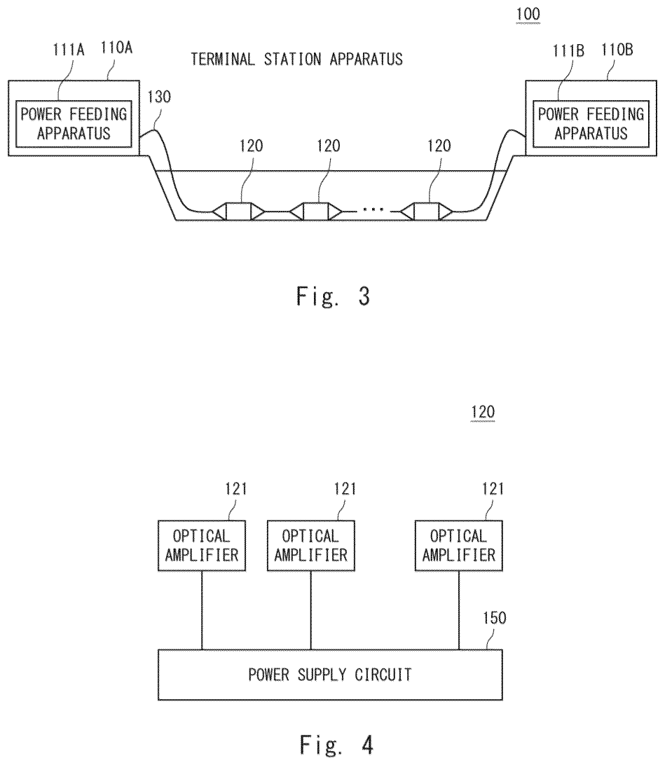

FIG. 3 illustrates one example of a communication system according to the present disclosure. One example embodiment will be described with reference to FIG. 3. A communication system 100 includes terminal station apparatuses 110A and 110B, and one or more optical repeaters 120. In the present example embodiment, the communication system 100 constitutes, for example, an optical submarine optical fiber cable system. The terminal station apparatus 110A corresponds to the first terminal station apparatus 11 illustrated in FIG. 1. The terminal station apparatus 110B corresponds to the second terminal station apparatus 12 illustrated in FIG. 1. The optical repeater 120 corresponds to the repeater 13 illustrated in FIG. 1.

The terminal station apparatuses 110A and 110B are connected to each other via a cable 130 such as a submarine cable. One or more optical repeaters 120 are connected in series to the cable 130. The terminal station apparatuses 110A and 110B communicate with each other via the cable 130. The cable 130 includes one or more optical fibers for optical signal transmission, and a power supply line. The cable 130 may include a pair (fiber pair) of an optical fiber for transmitting an optical signal from the terminal station apparatus 110A to the terminal station apparatus 110B, and an optical fiber for transmitting an optical signal from the terminal station apparatus 110B to the terminal station apparatus 110A.

For example, the terminal station apparatus 110A generates a wavelength multiplexing signal, and transmits the generated wavelength multiplexing signal to the opposite terminal station apparatus 110B via the cable 130. In addition, the terminal station apparatus 110B generates a wavelength multiplexing signal, and transmits the generated wavelength multiplexing signal to the opposite terminal station apparatus 110A via the cable 130.

The terminal station apparatuses 110A and 110B include power feeding apparatuses 111A and 111B, respectively. Each of the power feeding apparatuses 111A and 111B supplies power to each of the one or more optical repeaters 120 via a power supply line (e.g., a system cable) included in the cable 130. Each of the terminal station apparatuses 110A and 110B may monitor and control each optical repeater 120 by using the system cable. Each of the terminal station apparatuses 110A and 110B is also referred to as a land station.

FIG. 4 illustrates a configuration example of the optical repeater 120. The optical repeater 120 includes one or more optical amplifiers 121, and a power supply circuit 150. The optical repeater 120 includes, for example, a cylindrical container having a space for accommodating the one or more optical amplifiers 121 and the power supply circuit 150 therein. A housing is formed of a material having pressure resistance, water resistance, corrosion resistance, and the like, and being capable of being installed on the seabed for a long period of time. The optical amplifier 121 corresponds to the optical amplifier 16 illustrated in FIG. 2. The power supply circuit 150 corresponds to the power supply circuit 15 illustrated in FIG. 2.

Each of the one or more optical amplifiers 121 includes an amplifier amplifying power of a signal transmitted through an optical fiber included in the cable 130. Each optical amplifiers 121 is configured by using, for example, an erbium doped fiber amplifier (EDFA). Each optical amplifier 121 is disposed associated to a fiber pair included in the cable 130, for example. Instead of disposing the optical amplifier 121 for each fiber pair, the optical amplifier 121 may be disposed for each optical fiber. The power supply circuit 150 is connected to the power feeding apparatuses 111A and 111B of the terminal station apparatuses 110A and 110B via the system cable included in the cable 130. The power supply circuit 150 supplies power to an excitation light source of each optical amplifier 121.

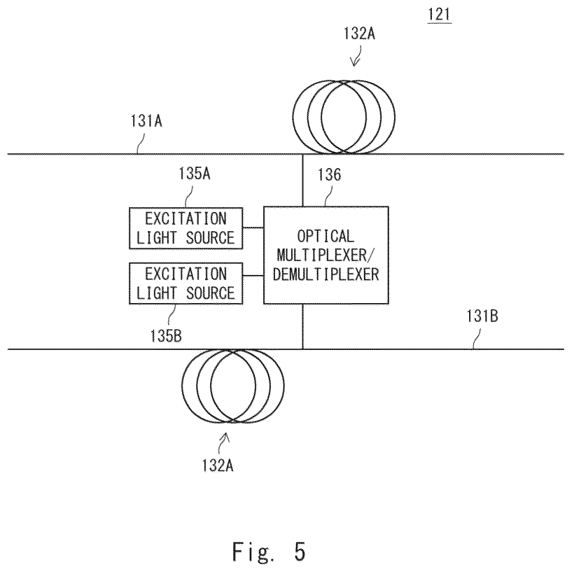

FIG. 5 illustrates a configuration example of the optical amplifier 121. The optical amplifier 121 includes erbium doped fibers (EDFs) 132A and 132B, excitation light sources 135A and 135B, and an optical multiplexer/demultiplexer 136. In the optical amplifier 121, the EDF 132A is inserted into the optical fiber 131A being one of the optical fibers of the fiber pair. The EDF 132B is inserted into the optical fiber 131B being the other optical fiber of the fiber pair.

Each of the excitation light sources 135A and 135B is a light source outputting excitation light to be inserted into the fiber pair. The excitation light sources 135A and 135B are connected in series to each other. Each of the excitation light sources 135A and 135B outputs, for example, continuous light having a predetermined wavelength. Each of the excitation light sources 135A and 135B includes, for example, a semiconductor laser. The excitation light sources 135A and 135B constitute an excitation laser module.

The excitation light output from the excitation light sources 135A and 135B is multiplexed in the optical multiplexer/demultiplexer 136, then demultiplexed into two, and inserted into the optical fibers 131A and 131B. The optical amplifier 121 may include a gain flattening filter associated to each of the optical fibers 131A and 131B.

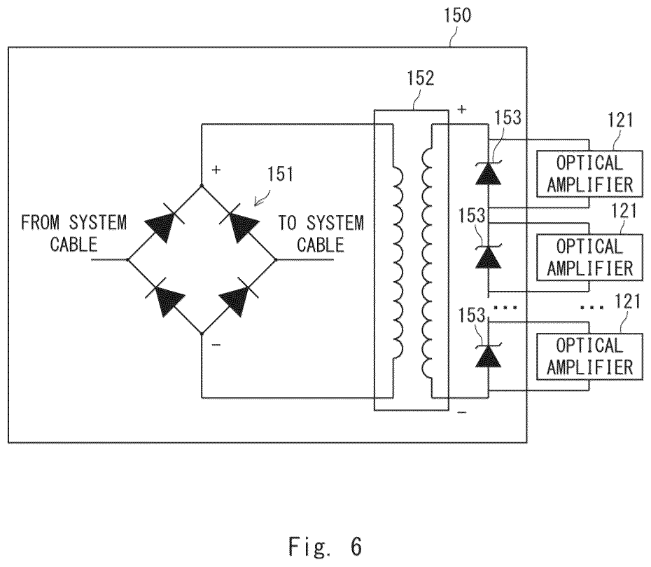

FIG. 6 illustrates a configuration example of the power supply circuit 150. The power supply circuit 150 includes a diode bridge 151, a DC/DC converter 152, and one or more Zener diodes 153. The DC/DC converter 152 corresponds to the DC/DC converter 21 illustrated in FIG. 2. The Zener diode 153 corresponds to the Zener diode 22 illustrated in FIG. 2.

The diode bridge 151 includes four diodes connected in a bridge configuration. The diode bridge 151 is connected in series to the system cable included in the cable 130. The diode bridge 151 outputs, to the DC/DC converter 152, a first current (also referred to as a system current) supplied from the terminal station apparatus 110A or 110B. Note that, in a case where only one of the terminal station apparatuses 110A and 110B includes the power feeding apparatus, that is, in a case where the system current is supplied to the optical repeater 120 from only one of the two terminal station apparatuses, the diode bridge 151 may be omitted in the power supply circuit 150.

The DC/DC converter 152 is a conversion apparatus that converts the system current (direct current) to be input via the diode bridge 151 into a second current larger than the system current. For example, in a case where the system current of 1.3 A is supplied from the system cable to each optical repeater 120, the DC/DC converter 152 outputs a current of 1.8 A.

One or more Zener diodes 153 are connected in series to an output terminal of the DC/DC converter 152. Each of the Zener diode 153 is disposed associated to the optical amplifier 121 included in the optical repeater 120. Each Zener diode 153 is connected in parallel with respect to the optical amplifier 121, in particular, to the excitation light sources 135A and 135B of the optical amplifier 121. Each optical amplifier 121 operates using a constant DC voltage appearing at both ends of each Zener diode 153 as a power source.

In the present example embodiment, the system current supplied from the terminal station apparatus 110A or 110B being a land station is supplied to each optical amplifier 121 via the DC/DC converter 152 installed at a subsequent stage of the diode bridge 151. By converting the system current into a larger current in the DC/DC converter 152, a current sufficient to increase the output of the excitation laser module can be supplied to each of the optical amplifiers 121.

By way of experiment, it is considered a case where the DC/DC converter 152 is omitted in the power supply circuit 150 illustrated in FIG. 6. In that case, the system current output from the diode bridge 151 is output directly to one or more Zener diodes 153. In this case, a current larger than the system current cannot be supplied to the optical amplifier 121. In contrast, in the present example embodiment, by using the DC/DC converter 152, a current larger than the system current can be supplied to each optical amplifier 121, and excitation light having a desired level can be acquired by the excitation laser module.

In comparison with Patent Literature 1, in Patent Literature 1, a DC/DC converter is connected to a subsequent stage of a Zener diode. In contrast, in the present example embodiment, the Zener diode is disposed at a subsequent stage of the DC/DC converter. In a case where a plurality of optical amplifiers are implemented on a repeater, in Patent Literature 1, it is required that a plurality of sets of Zener diodes and DC/DC converters are disposed. In contrast, in the present example embodiment, one DC/DC converter may be used. For this reason, the power supply circuit according to the present example embodiment can save space, as compared with the power supply circuit described in Patent Literature 1. In addition, in the power supply circuit described in Patent Literature 1, since a plurality of DC/DC converters are connected in multiple stages, conversion efficiency is lowered. In contrast, in the power supply circuit according to the present example embodiment, a plurality of DC/DC converters need not be connected in multiple stages. For this reason, the power supply circuit according to the present example embodiment can suppress a decrease in the conversion efficiency.

In the present example embodiment, configuration change of the optical repeater 120 only needs to add the DC/DC converter 152. In the present example embodiment, in the optical repeater 120, it is possible to increase the output of the excitation light without increasing the number of excitation laser modules. By way of experiment, when the excitation laser module is increased, it is necessary to add an optical coupler or the like, and it is necessary to change a configuration of an optical component that distributes the excitation light to the erbium doped fiber. In the present example embodiment, it is possible to increase the output of the excitation light without changing the configuration of the optical component, and it is possible to simplify structure of the optical repeater 120 and the optical amplifier 121, as compared with a case of changing the configuration of the optical component. Therefore, the present example embodiment can suppress an increase in size of the optical repeater 120.

While the present disclosure has been particularly shown and described with reference to example embodiments thereof, the present disclosure is not limited to these example embodiments. It will be understood by those of ordinary skill in the art that various changes in form and details may be made therein without departing from the sprit and scope of the present disclosure as defined by the claims. And each example embodiment can be appropriately combined with at least one of example embodiments.

Each of the drawings or figures is merely an example to illustrate one or more example embodiments. Each figure may not be associated with only one particular example embodiment, but may be associated with one or more other example embodiments. As those of ordinary skill in the art will understand, various features or steps described with reference to any one of the figures can be combined with features or steps illustrated in one or more other figures, for example to produce example embodiments that are not explicitly illustrated or described. Not all of the features or steps illustrated in any one of the figures to describe an example embodiment are necessarily essential, and some features or steps may be omitted. The order of the steps described in any of the figures may be changed as appropriate.

Some or all of the above-described example embodiments may be described as the following supplementary notes, but are not limited thereto.

### [Supplementary Note 1]

A power supply circuit including:

a direct current (DC)/DC converter connected in series to a cable including an optical fiber and a power supply line, and configured to amplify a current supplied via the power supply line; and

one or more Zener diodes connected in series with respect to an output current of the DC/DC converter, and each connected in parallel with respect to an optical amplifier amplifying a signal transmitted through the optical fiber.

### [Supplementary Note 2]

The power supply circuit according to supplementary note 1, further including a diode bridge on an input side of the DC/DC converter.

### [Supplementary Note 3]

The power supply circuit according to supplementary note 1 or 2, wherein the cable includes one or more fiber pairs that are a pair of a first optical fiber for transmitting a signal in a first direction and a second optical fiber for transmitting a signal in a second direction opposite to the first direction, and the optical amplifier is disposed for each of the fiber pairs.

### [Supplementary Note 4]

The power supply circuit according to any one of supplementary notes 1 to 3, wherein the optical amplifier includes an erbium doped fiber, and an excitation light source outputting excitation light to the erbium doped fiber.

### [Supplementary Note 5]

The power supply circuit according to supplementary note 4, wherein the excitation light source includes two semiconductor lasers connected in series to each other.

### [Supplementary Note 6]

The power supply circuit according to supplementary note 5, wherein the two semiconductor lasers are connected in parallel with respect to the Zener diode.

### [Supplementary Note 7]

A repeater including:

one or more optical amplifiers connected in series to a cable including an optical fiber and a power supply line, and each configured to amplify a signal transmitted through the optical fiber; and

a power supply circuit configured to supply a current to the one or more optical amplifiers, wherein

the power supply circuit includes

a direct current (DC)/DC converter configured to amplify a current supplied via the power supply line, and

one or more Zener diodes connected in series with respect to an output current of the DC/DC converter, and each connected in parallel with respect to the optical amplifier.

### [Supplementary Note 8]

The repeater according to supplementary note 7, wherein the power supply circuit further includes a diode bridge on an input side of the DC/DC converter.

### [Supplementary Note 9]

The repeater according to supplementary note 7 or 8, wherein the cable includes one or more fiber pairs that are a pair of a first optical fiber for transmitting a signal in a first direction and a second optical fiber for transmitting a signal in a second direction opposite to the first direction, and the optical amplifier is disposed for each of the fiber pairs.

### [Supplementary Note 10]

The repeater according to any one of supplementary notes 7 to 9, wherein the optical amplifier includes an erbium doped fiber, and an excitation light source outputting excitation light to the erbium doped fiber.

### [Supplementary Note 11]

The repeater according to supplementary note 10, wherein the excitation light source includes two semiconductor lasers connected in series to each other.

### [Supplementary Note 12]

The repeater according to supplementary note 11, wherein the two semiconductor lasers are connected in parallel with respect to the Zener diode.

### [Supplementary Note 13]

A communication system including:

a first and second terminal station apparatuses disposed on one end side and the other end side of a cable including an optical fiber and a power supply line; and

one or more repeaters inserted in series into the cable, wherein

each of the one or more repeaters includes

one or more optical amplifiers connected in series to the cable, and each configured to amplify a signal transmitted through the optical fiber, and

a power supply circuit supplying current to the one or more optical amplifiers, and

the power supply circuit includes

a direct current (DC)/DC converter configured to amplify a current supplied via the power supply line, and

one or more Zener diodes connected in series with respect to an output current of the DC/DC converter, and each connected in parallel with respect to an optical amplifier.

### [Supplementary Note 14]

The communication system according to supplementary note 13, wherein at least one of the first terminal station apparatus and the second terminal station apparatus includes a power feeding apparatus supplying current to the power supply line.

### [Supplementary Note 15]

A power feeding method in a repeater, including:

in a repeater inserted in series into a cable including an optical fiber and a power supply line, inputting a first current supplied via the power supply line to a direct current (DC)/DC converter;

converting the first current into a second current larger than the first current by using the DC/DC converter; and

supplying the second current from each of one or more Zener diodes connected in series with respect to an output terminal of the DC/DC converter to an optical amplifier amplifying a signal transmitted through the optical fiber.

Some or all of the elements (e.g., a configuration and a function) described in Supplementary notes 2 to 6 dependent on Supplementary note 1 (power supply circuit) may also be dependent on Supplementary note 13 (communication system) and Supplementary note 15 (power feeding method in the repeater) in dependency similar to that of Supplementary notes 2 to 6. Some or all of the elements described in any of Supplementary notes may be applied to various hardware, software, recording means for recording software, systems, and methods.

What is claimed is:

1. A power supply circuit comprising:
a direct current (DC)/DC converter connected in series to a cable including an optical fiber and a power supply line, and configured to amplify a current supplied via the power supply line; and
one or more Zener diodes connected in series with respect to an output current of the DC/DC converter, and each connected in parallel with respect to an optical amplifier amplifying a signal transmitted through the optical fiber.

2. The power supply circuit according to claim 1, further comprising a diode bridge on an input side of the DC/DC converter.

3. The power supply circuit according to claim 1, wherein the cable comprises one or more fiber pairs that are a pair of a first optical fiber for transmitting a signal in a first direction and a second optical fiber for transmitting a signal in a second direction opposite to the first direction, and the optical amplifier is disposed for each of the fiber pairs.

4. The power supply circuit according to claim 1, wherein the optical amplifier comprises an erbium doped fiber, and an excitation light source outputting excitation light to the erbium doped fiber.

5. The power supply circuit according to claim 4, wherein the excitation light source comprises two semiconductor lasers connected in series to each other.

6. The power supply circuit according to claim 5, wherein the two semiconductor lasers are connected in parallel with respect to the Zener diode.

7. A repeater comprising:
one or more optical amplifiers connected in series to a cable including an optical fiber and a power supply line, and each configured to amplify a signal transmitted through the optical fiber; and
a power supply circuit configured to supply a current to the one or more optical amplifiers, wherein
the power supply circuit comprises
a direct current (DC)/DC converter configured to amplify a current supplied via the power supply line, and
one or more Zener diodes connected in series with respect to an output current of the DC/DC converter, and each connected in parallel with respect to the optical amplifier.

8. The repeater according to claim 7, wherein the power supply circuit further comprises a diode bridge on an input side of the DC/DC converter.

9. The repeater according to claim 7, wherein the cable comprises one or more fiber pairs that are a pair of a first optical fiber for transmitting a signal in a first direction and a second optical fiber for transmitting a signal in a second direction opposite to the first direction, and the optical amplifier is disposed for each of the fiber pairs.

10. The repeater according to claim 7, wherein the optical amplifier comprises an erbium doped fiber, and an excitation light source outputting excitation light to the erbium doped fiber.

11. The repeater according to claim 10, wherein the excitation light source comprises two semiconductor lasers connected in series to each other.

12. The repeater according to claim 11, wherein the two semiconductor lasers are connected in parallel with respect to the Zener diode.

13. A power feeding method in a repeater, comprising:
in a repeater inserted in series into a cable including an optical fiber and a power supply line, inputting a first current supplied via the power supply line to a direct current (DC)/DC converter;
converting the first current into a second current larger than the first current by using the DC/DC converter; and
supplying the second current from each of one or more Zener diodes connected in series with respect to an output terminal of the DC/DC converter to an optical amplifier amplifying a signal transmitted through the optical fiber.
